(19) United States
(12) Patent Application Publication
(10) Pub. No.: US 2018/0307089 A1
(43) Pub. Date: Oct. 25, 2018

(54) LIQUID CRYSTAL DISPLAY DEVICE

(71) Applicant: Japan Display Inc., Minato-ku (JP)

(72) Inventors: Koichi Igeta, Tokyo (JP); Toshiharu Matsushima, Tokyo (JP)

(73) Assignee: Japan Display Inc., Minato-ku (JP)

(21) Appl. No.: 15/946,799

(22) Filed: Apr. 6, 2018

(30) Foreign Application Priority Data
Apr. 20, 2017 (JP) 2017-083851

(51) Int. Cl. G02F 1/1333; G02F 1/1337; G02F 1/1335; G02F 1/1343; H05K 1/18

(52) U.S. Cl. CPC G02F 1/133345; G02F 1/13338; G02F 1/1337; G02F 1/133514; G02F 2201/123; G02F 1/134309; H05K 1/189; G02F 2201/121; G02F 1/133512

(57) ABSTRACT

According to one embodiment, a liquid crystal display device includes first and second substrates and a liquid crystal layer. The first substrate includes scanning lines, signal lines, first and second electrodes and a light-shielding layer. One of the first and second electrodes is a pixel electrode, and the other one is a common electrode. The first electrode includes branch areas and an axis area. A gap area is provided between the adjacent branch areas. The light-shielding layer includes first portions overlapping the branch area or the gap area. The first portions are arranged at a position closer to the liquid crystal layer than the scanning and signal lines in the first substrate.

### CROSS-REFERENCE TO RELATED APPLICATIONS

This application is based upon and claims the benefit of priority from Japanese Patent Application No. 2017-083851, filed Apr. 20, 2017, the entire contents of which are incorporated herein by reference.

### FIELD

Embodiments described herein relate generally to a liquid crystal display device.

### BACKGROUND

As a display device, a liquid crystal display device conforming to an in-plane switching (IPS) mode is known. In an IPS mode liquid crystal display device, a pixel electrode and a common electrode are provided on one of a pair of substrates which are opposed to each other via a liquid crystal layer, and a lateral electric field which is produced between these electrodes is used for controlling the alignment of liquid crystal molecules of the liquid crystal layer. Further, a liquid crystal display device conforming to a fringe field switching (FFS) mode in the IPS mode in which a pixel electrode and a common electrode are provided on different layers is put into practical use. This liquid crystal display device uses a fringe field which is produced between a pair of electrodes for controlling the alignment of liquid crystal molecules.

Meanwhile, there is a liquid crystal display device in which a pixel electrode and a common electrode are provided on different layers, a slit is provided in an electrode closer to a liquid crystal layer, and liquid crystal molecules close to the sides of the slit in the width direction are rotated in opposite directions. This liquid crystal display device conforms to a mode which clearly differs from a conventionally-known FFS mode in terms of rotation of the liquid crystal molecules, and this mode can increase response speed and improve alignment stability as compared to the conventional FFS mode. The configuration of this liquid crystal display device will be hereinafter referred to as a high-speed response mode.

In a high-speed response mode liquid crystal display device, a liquid crystal layer tends to have many areas in which liquid crystal modules are not rotated even when voltage is applied. These areas may cause a decrease in contrast.

### BRIEF DESCRIPTION OF THE DRAWINGS

FIG. 1 is a perspective view schematically showing the structure of a liquid crystal display device according to the first embodiment.

FIG. 2 is a diagram schematically showing the equivalent circuit of the liquid crystal display device according to the first embodiment.

FIG. 3 is a plan view schematically showing an example of a sub-pixel in the first embodiment.

FIG. 4 is a graph showing results of luminance measurement along line IV-IV shown in FIG. 3 in (A) an off state and (B) an on state.

FIG. 5 is a plan view schematically showing an arrangement example of a light-shielding layer in the first embodiment.

FIG. 6 is a sectional view schematically showing the liquid crystal display device according to the first embodiment.

FIG. 7 is a graph showing results of luminance measurement in (A) the off state and (B) the on state when a first light-shielding layer is provided.

FIG. 8 is a sectional view schematically showing a display device according to a comparative example of the first embodiment.

FIG. 9 is a graph showing results of viewing angle simulation.

FIG. 10 is a sectional view schematically showing a modification of the arrangement position of a second light-shielding layer.

FIG. 11 is a sectional view schematically showing another modification of the arrangement position of the second light-shielding layer.

FIG. 12 is a plan view of the second light-shielding layer showing an effect of the modification.

FIG. 13 is a plan view schematically showing a first area in the second embodiment.

FIG. 14 is a plan view schematically showing an arrangement example of a light-shielding layer in the second embodiment.

FIG. 15 is a plan view schematically showing a liquid crystal display device according to the third embodiment.

FIG. 16 is a plan view schematically showing a common electrode in the third embodiment.

FIG. 17 is a sectional view schematically showing the liquid crystal display device according to the third embodiment.

FIG. 18 is a plan view schematically showing an arrangement example of a first light-shielding layer in the third embodiment.

FIG. 19 is a plan view schematically showing a liquid crystal display device according to the fourth embodiment.

FIG. 20 is a plan view schematically showing an arrangement example of a first light-shielding layer in the fourth embodiment.

FIG. 21 is a plan view schematically showing a liquid crystal display device according to the fifth embodiment.

FIG. 22 is a sectional view schematically showing the structure of a first substrate applicable to the fifth embodiment.

FIG. 23 is a sectional view schematically showing the structure of the first substrate applicable to the fifth embodiment.

FIG. 24 is a plan view schematically showing a common electrode and a pixel electrode according to the sixth embodiment.

FIG. 25 is a sectional view partially showing a liquid crystal display device according to the sixth embodiment.

FIG. 26 is another sectional view showing the structure of a first substrate applicable to the sixth embodiment.

### DETAILED DESCRIPTION

In general, according to one embodiment, a liquid crystal display device includes a first substrate, a second substrate opposed to the first substrate, and a liquid crystal layer located between the first substrate and the second substrate. The first substrate includes a plurality of scanning lines, a plurality of signal lines which intersect the scanning lines, a first electrode, a second electrode opposed to the first electrode, and a light-shielding layer. One of the first electrode and the second electrode is a pixel electrode, and the other one of the first electrode and the second electrode is a common electrode. The first electrode includes a plurality of branch areas which extend in a first direction, and an axis area which extends in a second direction intersecting the first direction and connects the branch areas. A gap area is provided between the branch areas which are adjacent to each other, and the gap area extends in the first direction. The light-shielding layer includes a plurality of first portions, each of the first portions overlaps the branch area or the gap area, and the first portions extend in the first direction and are arranged in the second direction. The first portions are arranged at a position which is closer to the liquid crystal layer than the scanning lines and the signal lines in the first substrate. According to this structure, a liquid crystal display device conforming to a high-speed response mode which is improved in contrast can be obtained.

Embodiments will be described with reference to accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, illustration is provided in the drawings schematically, rather than as an accurate representation of what is implemented. However, such schematic illustration is merely exemplary and in no way restricts the interpretation of the invention. In the drawings, reference numbers of continuously arranged elements equivalent or similar to each other are omitted in some cases. In addition, in the specification and drawings, structural elements equivalent or similar to those described in connection with preceding drawings are denoted by the same reference numbers, and detailed description thereof is omitted unless necessary.

In the specification, such expressions as “α includes A, B or C”, “α includes any one of A, B and C” and “α includes an element selected from a group consisting of A, B and C” do not exclude a case where α includes varying combinations of A, B and C unless otherwise specified. Still further, these expressions do not exclude a case where a includes other elements.

In the specification, “the first, the second and the third” in such an expression as “the first α, the second α and the third α” are mere numbers used for the sake of convenience of explaining elements. That is, such an expression as “A includes the third 3α” also includes a case where A does not include the first α and the second α unless otherwise specified.

In the embodiments, a transmissive liquid crystal display device will be described as an example of the liquid crystal display device. However, the embodiments do not preclude the application of individual technical ideas disclosed in the embodiments to other display devices. The other display devices are assumed be a reflective liquid crystal display device which displays an image by using external light, a liquid crystal display device having both the function of a transmissive liquid crystal display and the function of a reflective liquid crystal display device, etc.

### First Embodiment

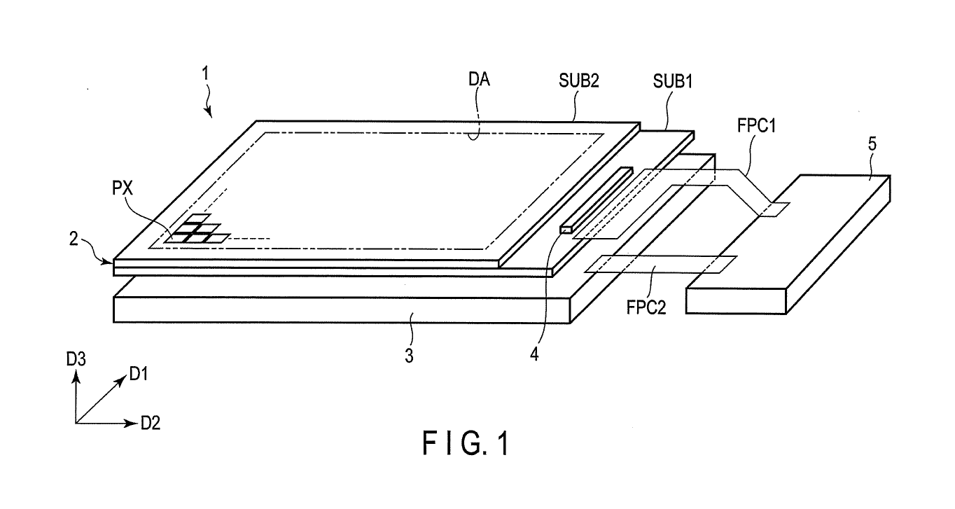

FIG. 1 is a perspective view schematically showing the structure of a liquid crystal display device 1 (hereinafter referred to as a display device 1) according to the first embodiment. The display device 1 can be used in various devices such as smartphones, tablet computers, mobile phones, personal computers, television receivers, vehicle-mounted devices, game consoles and wearable devices, for example.

The display device 1 includes a display panel 2, a backlight 3 which is opposed to the display panel 2, a driver IC 4 which drives the display panel 2, a control module 5 which controls the operations of the display panel 2 and the backlight 3, and flexible printed circuit boards FPC1 and FPC2 which transmit control signals to the display panel 2 and the backlight 3.

In the present embodiment, a first direction D1 is an extension direction of a branch area 40 which will be described later, a second direction D2 is an extension direction of an axis area 30 which will be described later, and a third direction D3 is a direction which intersects the directions D1 and D2. In FIG. 1, the first direction D1 also corresponds to a direction along the short sides of the display panel 2. The second direction D2 also corresponds to a direction along the long sides of the display panel 2, for example. The directions D1, D2 and D3 perpendicularly intersect each other in the example shown in FIG. 1, but the directions D1, D2 and D3 may intersect each other at other angles.

The display panel 2 includes a first substrate SUB1 and a second substrate SUB2 which are opposed to each other, and a liquid crystal layer (liquid crystal layer LC which will be described layer) which is arranged between the substrates SUB1 and SUB2. The display panel 2 has a display area DA on which an image is displayed. The display panel 2 includes a plurality of pixels PX which are arranged in a matrix in the directions D1 and D2, for example, in the display area DA.

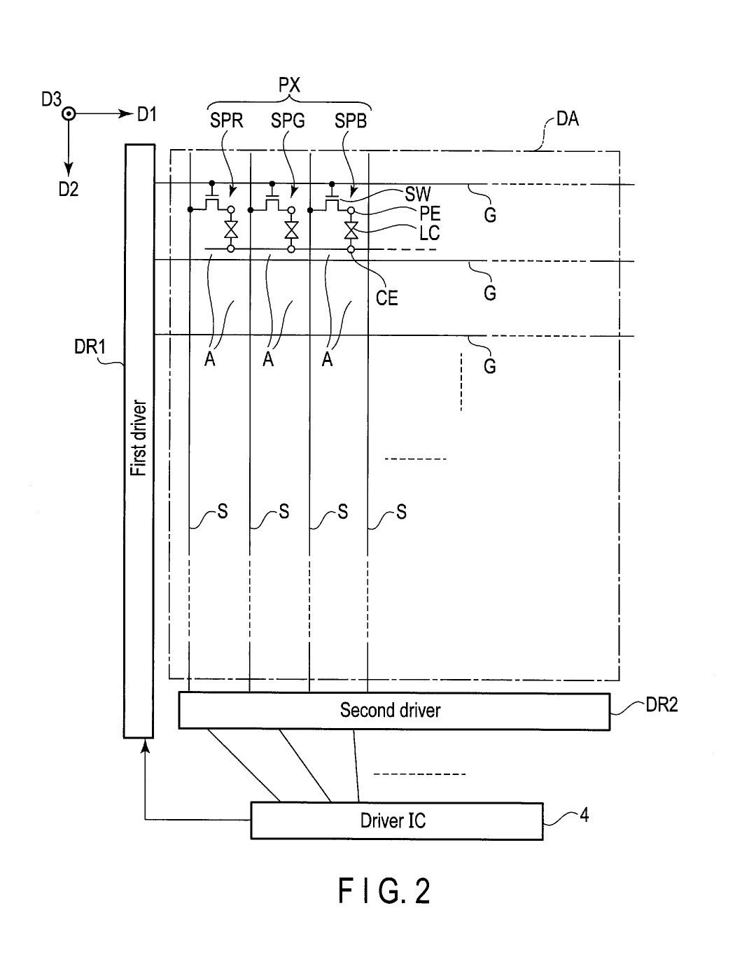

FIG. 2 is a diagram schematically showing the equivalent circuit of the display device 1. The display device 1 includes a first driver DR1, a second driver DR2, a plurality of scanning lines G (gate lines) which are connected to the first driver DR1, and a plurality of signal lines S (source lines) which are connected to the second driver DR2. The scanning lines G extend in the first direction D1 and are arranged in the second direction D2 in the display area DA. The signal lines S extend in the second direction D2 and are arranged in the first direction D1 in the display area DA, and intersect the scanning lines C, respectively.

The display device 1 has a plurality of sub-pixel areas A. The sub-pixel areas A are partitioned with the scanning lines G and the signal lines S in a plan view. Sub-pixels SP are formed in the sub-pixel areas A. In the present embodiment, one pixel PX is assumed to include one sub-pixel SPR for red display, one sub-pixel SPG for green display and one sub-pixel SPB for blue display. However, the pixel PX may further include a sub-pixel SP for white display or may include a plurality of sub-pixels SP corresponding to the same color.

Each sub-pixel SP includes a switching element SW, a first electrode and a second electrode which is opposed to the first electrode. One of the first electrode and the second electrode is a pixel electrode PE, and the other one of the first electrode and the second electrode is a common electrode CE. The pixel electrode PE and the common electrode CE are formed of a transparent conductive material such as indium tin oxide (ITO), for example. The common electrode CE is formed over a plurality of sub-pixels SP. A common potential is applied to the common electrode CE. The switching element SW is connected to the scanning line G, the signal line S and the pixel electrode PE. The pixel electrode PE is electrically connected to the signal line S via the switching element SW.

The first driver DR1 supplies scanning signals to the scanning lines G. The second driver DR2 supplies video signal lines to the signal lines S. When a scanning signal is supplied to the scanning line G corresponding to a certain switching element SW and a video signal is supplied to the signal line S connected to this switching element SW, a pixel potential corresponding to this video signal is applied to the pixel electrode PE. Accordingly, an electric field is generated between the pixel electrode PE and the common electrode CE, and the alignment of liquid crystal molecules of the liquid crystal layer LC is changed from an initial alignment state in which no voltage is applied. Through this operation, an image is displayed on the display area DA.

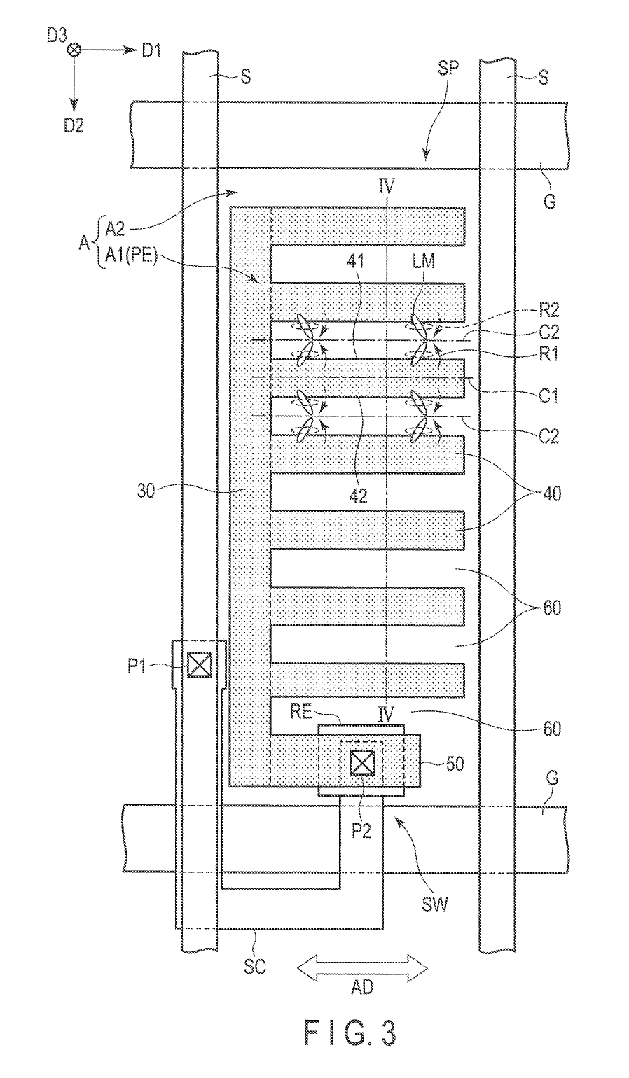

FIG. 3 is a plan view schematically showing an example of the sub-pixel SP. The sub-pixel area A is formed by two scanning lines G which are adjacent to each other in the second direction D2 and two signal lines S which are adjacent to each other in the first direction D1. The sub-pixel area A has a first area A1 and a second area A2. In FIG. 3, a dot pattern is added to the first area A1. The second area A2 has the shape of an area which remains after the first area A1 is excluded from the sub-pixel area A. In the present embodiment, the first area A1 is an area in which the pixel electrode PE is provided, and the second area A2 is an area in which the pixel electrode PE is not provided.

The first area A1 has an axis area 30 and a plurality of branch areas 40. The axis area 30 extends in the second direction D2. The branch areas 40 extend in the first direction D1 and are arranged in the second direction D2. One end of each branch area 40 is connected to the axis area 30. In FIG. 3, each branch area 40 has a constant width in the second direction D2 from a proximal end to a distal end. However, each branch area 40 may taper down toward the distal end or may have another shape.

Each branch area 40 has a first side 41 and a second side 42. In the example shown in FIG. 3, these sides 41 and 42 are parallel to the first direction D1 but may be inclined with respect to the first direction D1.

In FIG. 3, the first area A1 further has an end area 50. The end area 50 is connected to the axis area 30 and extends in the first direction D1 as is the case with the branch areas 40. The end area 50 is wider than the branch areas 40 in the second direction D2 and is shorter than the branch areas 40 in the first direction D1.

The second area A2 has a gap area 60 elongated in the first direction D1 between two branch areas 40 which are adjacent to each other in the second direction D2. The gap area 60 is also formed between the end area 50 and the branch area 40 which is adjacent to the end area 50.

In the example shown in FIG. 3, all the branch areas 40 have the shape and are arranged at the same pitch in the second direction D2. Similarly, all the gap areas 60 have the same shape and are arranged at the same pitch in the second direction D2. However, all the branch areas 40 and the gap areas 60 do not necessarily have the same shape, and some of the branch areas 40 and the gap areas 60 may have different shapes.

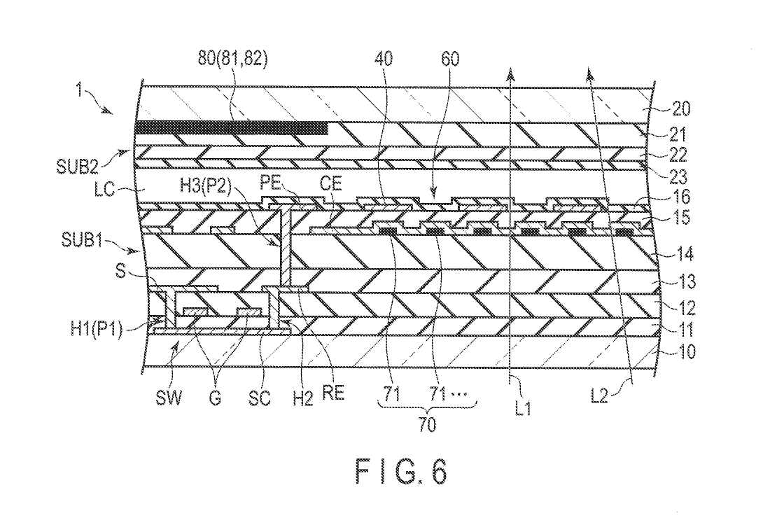

The switching element SW includes a semiconductor layer SC. The semiconductor layer SC is connected to the signal line S at a connection position P1 and is connected to the pixel electrode PE at a connection position P2. In the example shown in FIG. 3, the connection position P2 is included in the end area 50. The semiconductor layer SC intersects the scanning line G on the lower side of the drawing twice. That is, the drawing shows a case where the switching element SW is a double-gate switching element. However, the switching element SW may be a single-gate switching element which intersects the scanning line G one time. In a first alignment film 16 and a second alignment film 23 shown in FIG. 6 which will be described later, alignment treatment is applied in an alignment treatment direction AD which is parallel to the first direction D1. Therefore, the first alignment film 16 and the second alignment film 23 have the function of aligning the liquid crystal molecules with an initial alignment direction which is parallel to the alignment treatment direction AD. That is, the extension direction of the branch areas 40 and the initial alignment direction of the liquid crystal molecules are equal to each other in the present embodiment.

According to the shape of the pixel electrode PE in the present embodiment, the high-speed response mode in which response speed is higher than that of the common FFS mode can be realized. The response speed here can be defined as the speed with which the light transmittance of the liquid crystal layer LC transitions within a predetermined level when voltage is applied between the pixel electrode PE and the common electrode CE, for example. The principle of the high-speed response mode will be briefly described below. The principle of the high-speed response mode is disclosed in more details in JP 2015-215493 A, etc.

Liquid crystal molecules LM in the present embodiment have positive dielectric anisotropy. In a state where voltage is not applied between the pixel electrode PE and the common electrode CE, as shown as ellipses by dashed lines in FIG. 3, the liquid crystal molecules LM are initially aligned such that major axes thereof will coincide with the alignment treatment direction AD.

When voltage is applied between the pixel electrode PE and the common electrode CE, a rotative force acts on the liquid crystal molecules LM such that the major axes will be parallel to the direction of an electric field generated by voltage application. As a result, the liquid crystal molecules LM rotate in a first rotation direction R1 shown by a solid arrow in the vicinity of the first side 41 of the branch area 40. Further, the liquid crystal molecules LM rotate in a second rotation direction R2 shown by a dashed arrow in the vicinity of the second side 42 of the branch area 40. The first rotation direction R1 and the second rotation direction R2 are different directions from each other (opposite rotation directions to each other).

On the other hand, the liquid crystal molecules LM which rotate in the first rotation direction R1 and the liquid crystal molecules LM which rotate in the second rotation direction R2 are balanced with each other in the vicinities of a center C1 of the branch area 40 in the second direction D2 and a center C2 of the gap area 60. Therefore, the liquid crystal molecules LM in these areas are maintained in the initial alignment state and hardly rotate.

As described above, in the high-speed response mode, the rotation directions of the liquid crystal molecules LM are aligned from the proximal end to the distal end in the vicinity of the sides 41 and 42, respectively. Accordingly, the response speed at the time of voltage application can be increased, and besides, variations in the rotation directions of the liquid crystal molecules LM can be reduced and the alignment stability can be improved.

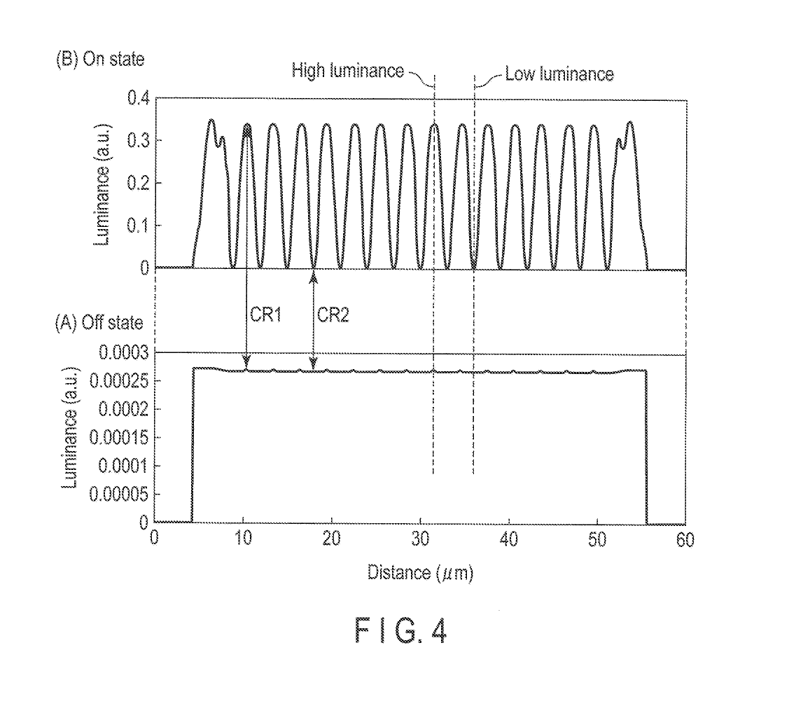

FIG. 4 is a graph showing results of luminance measurement along line IV-IV shown in FIG. 3 in (A) an off state in which voltage is not applied between the pixel electrode PE and the common electrode CE and (B) an on state where voltage is applied between the pixel electrode PE and the common electrode CE. In the measurement, a sub-pixel area which has more branch areas 40 than the sub-pixel area A shown in FIG. 3 is used as a model, and a first light-shielding layer 70 which will be described later is not provided. The horizontal axis shows a distance [μm] from an arbitrary reference point (O). The vertical axis shows a luminance in an arbitrary unit [a.u.].

In the off state, the light from the backlight 3 slightly transmits and has an extremely low and uniform luminance distribution as a whole. In the on state, on the other hand, the luminance is high in the vicinities of the sides 41 and 42 of the branch area 40 since the liquid crystal molecules LM rotate there, and the luminance is low in the vicinities of the centers C1 and C2 since the liquid crystal molecules LM do not rotate there as described above. Therefore, the light has such a luminance distribution that a high luminance area and a low luminance area are repeated alternately.

In the high luminance area, a contrast ratio CR1 between the off state and the on state becomes high. On the other hand, a contrast ration CR2 between the off state and the on state becomes low in the low luminance area. In the high-speed response mode, the sub-pixel area A contains many areas having the low contrast ratio CR2. Consequently, the overall contrast ratio of the sub-pixel area A is reduced, and the display quality may be degraded. In the on state, on the other hand, the low luminance area does not substantially contribute to improvement of the luminance of the sub-pixel area A.

In the present embodiment, the contract ratio of the sub-pixel area A is improved by shielding an appropriate position (low luminance area) of the sub-pixel area A from light by a light-shielding layer. Now, the arrangement of the light-shielding layer will be described.

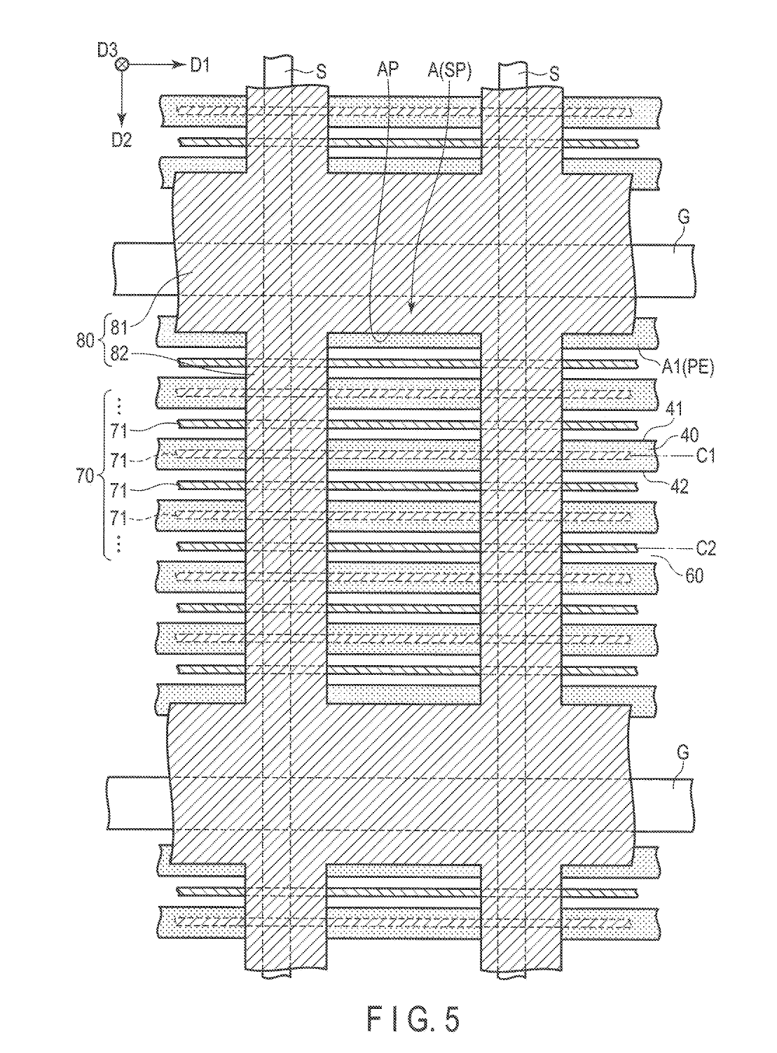

FIG. 5 is a plan view schematically showing an arrangement example of the light-shielding layer in the present embodiment. The drawing focuses on one sub-pixel area A (sub-pixel SP) as is the case with FIG. 3 and shows two scanning lines G, two signal lines S and the pixel electrode PE in addition to the light-shielding layer. In the example shown in FIG. 5, a first light-shielding layer 70 and a second light-shielding layer 80 are arranged as the light-shielding layer.

The second light-shielding layer 80 includes a plurality of scanning line light-shielding portions 81 which overlap the respective scanning lines G and are elongated in the first direction D1, and a plurality of signal line light-shielding portions 82 which overlap the respective signal lines S and are elongated in the second direction D2. These light-shielding portions 81 and 82 also overlap the switching element SW. Further, the signal line light-shielding portions 82 overlap the axis area 30 and the distal ends of the branch areas 40. However, part of the axis area 30 and the distal ends of the branch areas 40 may not overlap the signal line light-shielding portions 82. An aperture AP formed by the light-shielding portions 81 and 82 is an area which substantially contributes to image display.

The first light-shielding layer 70 includes a plurality of first portions 71 which extend in the first direction D1 and are arranged in the second direction D2. The first portions 71 overlap the centers C1 of the branch areas 40 and the centers C2 of the gap areas 60. The first portions 71 do not overlap the vicinities of the first sides 41 and the second sides 42 of the branch areas 40. From another perspective, the first portion 71 which overlaps the center C1 is narrower than the branch area 40 in the second direction D2. Further, the first portion 71 which overlaps the center C2 is narrower than the gap area 60 in the second direction D2. The width in the second direction D2 may vary between the first portion 71 which overlaps the branch area 40 and the first portion 71 which overlaps the gap area 60.

For example, the sub-pixel area A has a width of 20 μm in the first direction D1 and a width of 60 μm in the second direction D2, and the branch areas 40 and the gap areas 60 have a width of 3 μm in the second direction D2. In this case, for example, the first portions 71 may have a width of 1 μm in the second direction D2, the scanning line light-shielding portions 81 may have a width of 25 μm in the second direction D2, and the signal line light-shielding portions 82 may have a width of 10 μm in the second direction D2. These numerical values are presented by way of example only and are not intended to limit the widths of these portions.

In the example shown in FIG. 5, the first portions 71 are elongated over three sub-pixel areas A which are arranged in the first direction D1. In this case, the first portions 71 overlap the signal lines S between the adjacent sub-pixel areas A. The first portions 71 may be elongated over four or more sub-pixel areas A. Alternatively, the first portions 71 may be elongated between adjacent signal lines S and may not overlap these signal lines S.

FIG. 6 is a schematic sectional view of the display device 1. The first substrate SUB1 includes a first base 10 formed of glass or resin, a first insulating layer 11, a second insulating layer 12, a third insulating layer 13, a fourth insulating layer 14, a fifth insulating layer 15 and a first alignment film 16. The first substrate SUB1 further includes the signal line S, the scanning line G, the switching element SW, the pixel electrode PE, the common electrode CE and the first light-shielding layer 70.

The semiconductor layer SC of the switching element SW is arranged on the first base 10. The first insulating layer 11 covers the semiconductor layer SC and the first base 10. The scanning line G is arranged on the first insulating layer 11. The second insulating layer 12 covers the scanning line G and the first insulating layer 11. The signal line G and a relay electrode RE are arranged on the second insulating layer 12. The signal line S contacts the semiconductor layer SC via a contact hole H1 which penetrates the insulating layers 11 and 12 at the connection position P1 shown in FIG. 3. The relay electrode RE contacts the semiconductor layer SC via a contact hole H2 which penetrates the insulating layers 11 and 12. The third insulating layer 13 covers the signal line S, the relay electrode RE and the second insulating layer 12. The fourth insulating layer 14 is an organic resin layer which is thicker than the other insulating layers 11 to 13 and 15, for example, and levels unevenness caused by the switching element SW, etc.

In the example shown in FIG. 6, the first light-shielding layer 70 (the first portions 71) is arranged on the fourth insulating layer 14. For example, the first light-shielding layer 70 is formed of an insulating resin material. The first light-shielding layer 70 may include a conductive layer such as a metal layer. The common electrode CE is arranged on the fourth insulating layer 14 and the first light-shielding layer 70. The fifth insulating layer 15 is arranged on the common electrode CE and the fourth insulating layer 14. The pixel electrode PE is arranged on the fifth insulating layer 15 and contacts the relay electrode RE via a contact hole H3 which penetrates the insulating layers 13 to 15 at the connection position P2 shown in FIG. 3. The first alignment film 16 covers the pixel electrode PE and the fifth insulating layer 15.

The second substrate SUB 2 includes a second base 20 formed of glass or resin, a color filter layer 21, an overcoat layer 22 and a second alignment film 23. The second substrate SUB2 further includes the second light-shielding layer 80.

In the example shown in FIG. 6, the second light-shielding layer 80 is arranged under the second base 20. The color filter layer 21 covers the second light-shielding layer 80 and the second base 20. The overcoat layer 22 covers the color filter layer 21. The second alignment film 23 covers the overcoat layer 22. The liquid crystal layer LC is arranged between the first alignment film 16 and the second alignment film 23.

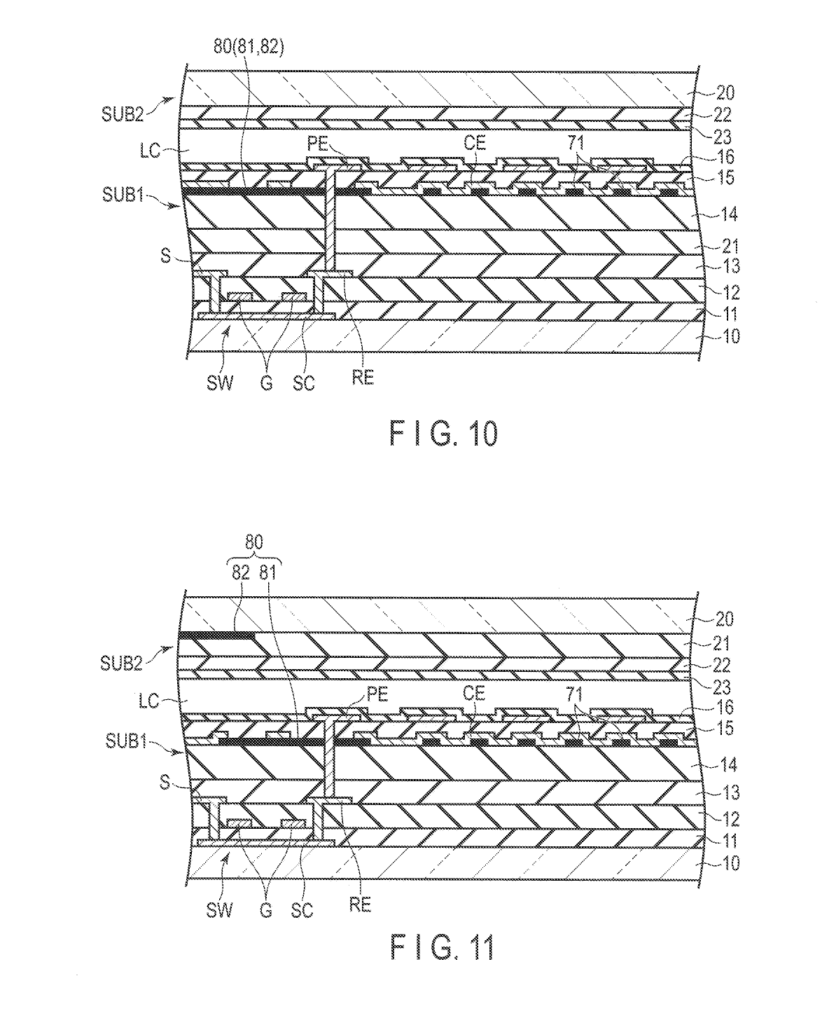

As described above, in the example shown in FIG. 6, the first light-shielding layer 70 is arranged on the first substrate SUB1, and the second light-shielding layer 80 is arranged on the second substrate SUB2. Further, on the first substrate SUB1, the first light-shielding layer 70 is arranged at a position closer to the liquid crystal layer LC (on a layer closer to the liquid crystal layer LC) than the elements which constitute the switching element SW, that is, the scanning line G, the signal line S, the semiconductor layer SC and the relay electrode RE. The light-shielding layers 70 and 80 are not necessarily arranged in this manner and can adopt various other arrangement manners such as those shown in FIGS. 10 and 11 which will be described later, for example.

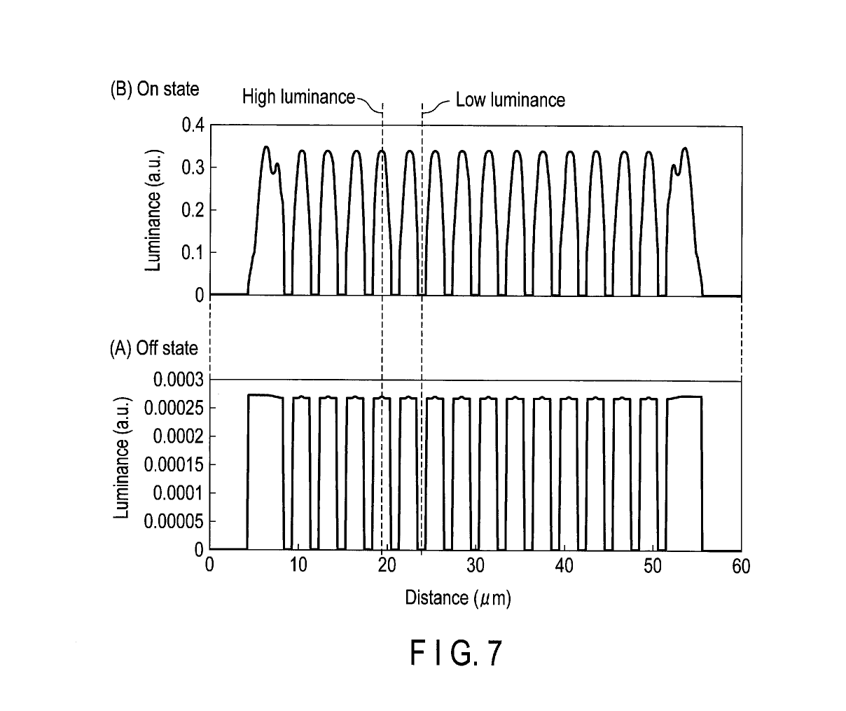

FIG. 7 is a graph showing results of luminance measurement of the sub-pixel area A in (A) the off state and (B) the on state as is the case with FIG. 4 when the first light-shielding layer 70 is provided. The vicinities of the centers of the branch areas 40 and the vicinities of the centers of the gap areas 60 are shielded from light by the first portions 71 of the light-shielding layer 70. Therefore, in both the off state and the on state, luminance becomes zero at positions at which the first portions 71 are arranged. The contrast ratio CR1 of the high-luminance area has the same value as that of the case shown in FIG. 4.

That is, when the first portions 71 are provided, the overall luminance of the sub-pixel area A in the off state can be significantly reduced, and the overall luminance of the sub-pixel area A in the on state can be maintained. As a result, the contrast ratio of the sub-pixel electrode A can be improved without substantially changing the overall luminance of the sub-pixel area A in the on state.

Further, when the first portions 71 of the first light-shielding layer 70 are arranged as in the example shown in FIG. 6, the following favorable effect can be produced.

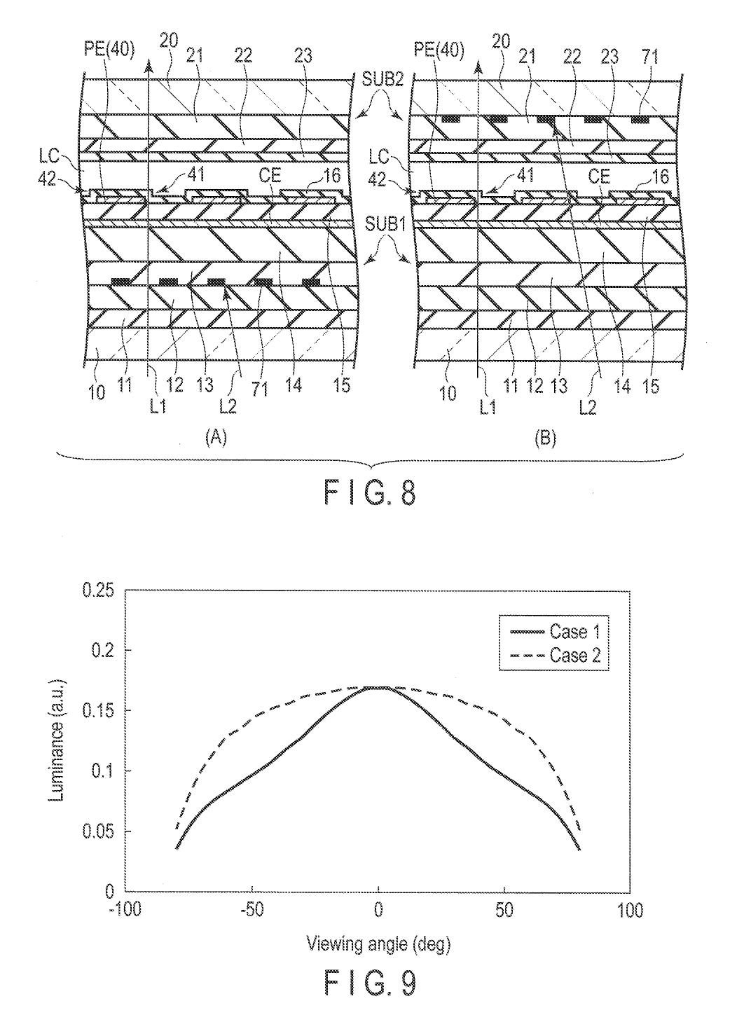

FIG. 8 is a sectional view schematically showing a display device according to a comparative example of the present embodiment. In a comparative example shown in FIG. 8 (A), the first portions 71 of the first light-shielding layer 70 are arranged above the second insulating layer 12 and are covered with the third insulating layer 13. In a comparative example shown in FIG. 8 (B), the first portions 71 are arranged below the second base 20 and are covered with the color filter layer 21.

As described above, the liquid crystal molecules included in the liquid crystal layer LC rotate in the vicinities of the sides 41 and 42 of the branch areas 40. In either comparative example, light L1 in the frontal direction (third direction D3) of the display device is excellently transmitted through the substrates SUB1 and SUB2 in the vicinities of the sides 41 and 42. On the other hand, in the comparative example shown in FIG. 8 (A), many insulating layers are interposed between the first portions 71 and the liquid crystal layer LC, and the first insulating layer 14 is relatively thick, and therefore the distance between the first portions 71 and the liquid crystal layer LC is large. Consequently, part of light L2 which is inclined with respect to the frontal direction and is directed to the vicinities of the sides 41 and 42 may be blocked by the first portions 71. Similarly, in the comparative example shown in FIG. 8 (B), the color filter layer 21 and the overcoat layer 22 are interposed between the first portions 71 and the liquid crystal layer LC, and the color filter layer 21 is relatively thick, and therefore the distance between the first portions 71 and the liquid crystal layer LC is large. Consequently, part of light L2 which is inclined with respect to the frontal direction and is transmitted through the vicinities of the sides 41 and 42 may be blocked by the first portions 71.

As described above, these comparative examples have a high dependence on the viewing angle of a display device. On the other hand, the distance between the first portions 71 and the liquid crystal layer LC is small in the example shown in FIG. 6. Therefore, the light L2 which is inclined with respect to the frontal direction and is transmitted through the vicinities of the sides 41 and 42 can be excellently transmitted through the substrates SUB1 and SUB2 without being blocked by the first portions 71. This improves the dependence of the display device 1 on the viewing angle.

FIG. 9 is a graph showing results of viewing angle simulation in a case (case 1) where the first portions 71 are provided as shown in FIG. 8 (B) and a case (case 2) where the first portions 71 are provided as shown in FIG. 6. The horizontal axis shows a viewing angle [deg], and the vertical axis shows luminance in an arbitrary unit [a.u.]. In case 1, as the viewing angle increases in the positive direction or the negative direction from zero, the luminance drops sharply. In case 2, on the other hand, the luminance decreases more gradually as compared to case 1 even if the viewing angle increases in the positive direction or the negative direction from zero. These results show that the dependence on the viewing angle can be improved by providing the first portions 71 as shown in FIG. 6.

The arrangement position of the first portions 71 is not limited to the example shown in FIG. 6. For example, the first portions 71 can be arranged between the common electrode CE and the fifth insulating layer 15, between the fifth insulating layer 15 and the pixel electrode PE, between the pixel electrode PE and the first alignment film 16, etc.

The arrangement position of the second light-shielding layer 80 can also be modified in various manners. FIG. 10 is a sectional view schematically showing a modification of the arrangement position of the second light-shielding layer 80. In the modification, the second light-shielding layer 80 is arranged on the first substrate SUB1. Further, the color filter layer 21 is also arranged on the first substrate SUB 1. More specifically, the second light-shielding layer 80 is arranged on the fourth insulating layer 14 and is covered with the common electrode CE and the fifth insulating layer 15. The color filter layer 21 is arranged on the third insulating layer 13 and is covered with the fourth insulating layer 14. However, the second light-shielding layer 80 and the color filter layer 21 may be arranged on other layers on the first substrate SUB1.

FIG. 11 is a sectional view schematically showing another modification of the arrangement position of the second light-shielding layer 80. In the example illustrated, the scanning line light-shielding portion 81 of the second light-shielding layer 80 is arranged on the first substrate SUB1, and the signal line light-shielding portion 82 is arranged on the second substrate SUB2. More specifically, the scanning line light-shielding portion 81 is arranged on the fourth insulating layer 14 and is covered with the common electrode CE and the fifth insulating layer 15. The signal line light-shielding portion 82 is arranged on the lower side of the second base 20 and is covered with the color filter layer 21. The scanning line light-shielding portions 81 may be arranged on another layer on the first substrate SUB1.

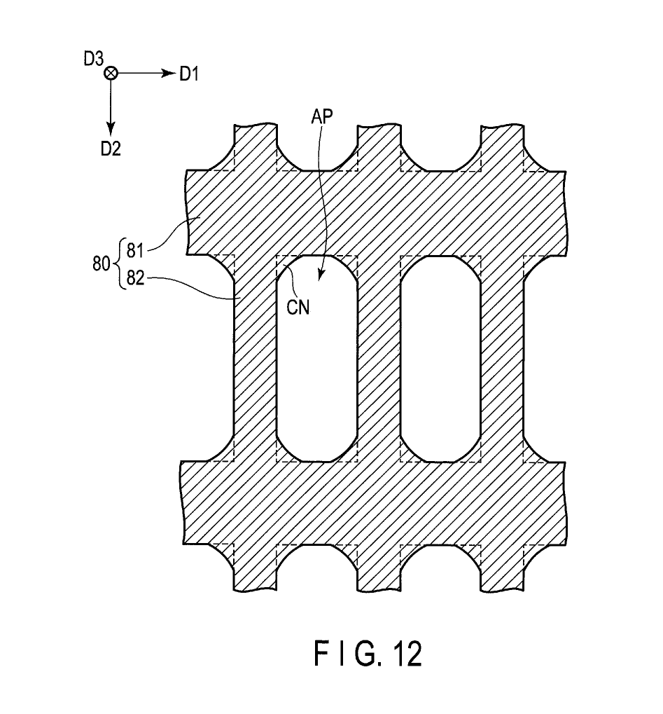

Now, an effect to be produced by arranging the portions 81 and 82 of the second light-shielding layer 80 on different substrates as described above will be described with reference to FIG. 12. If both of the portions 81 and 82 of the second light-shielding layer 80 are provided on either the first substrate SUB1 or the second substrate SUB2, corners CN of the intersection areas of the portions 81 and 82 cannot be perpendicularly formed due to limitations in the accuracy of manufacturing processes. As a result, the second light-shielding layer 80 may be formed in the vicinities of the corners CN which are designed as the aperture AP, and the aperture ratio may be reduced.

On the other hand, if the portions 81 and 82 of the second light-shielding layer 80 are arranged on different substrates as shown in FIG. 11, the portions 81 and 82 only need to be linearly formed on the respective substrates. Therefore, the corners CN of the intersection areas of the portions 81 and 82 can be formed as designed, and the aperture ratio will not be reduced.

### Second Embodiment

The second embodiment will be described. Another example of the shape of the first area A1 (pixel electrode PE) will be disclosed in the present embodiment. Unless otherwise specified, the present embodiment has the same structure and effect as those of the first embodiment.

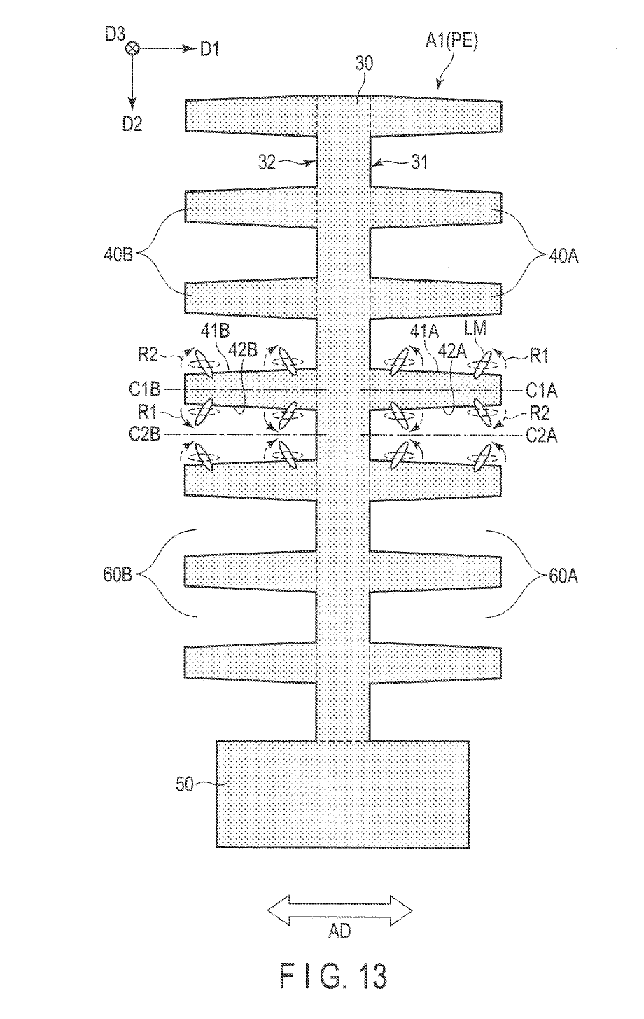

FIG. 13 is a plan view schematically showing the shape of the first area A (pixel electrode PE) in the present embodiment. The first area A1 has the axis area 30, a plurality of first branch areas 40A, a plurality of second branch areas 40B and the end area 50.

The axis area 30 has a first side 31 and a second side 32. The first branch areas 40A extend in the first direction D1 and are arranged in the second direction D2. One end of each first branch area 40A is connected to the first side 31 of the axis area 30. The second branch areas 40B extend in the first direction D1 and are arranged in the second direction D2. One end of each second branch area 40B is connected to the second side 32 of the axis area 30.

In the example shown in FIG. 13, each first branch area 40A and each second branch area 40B taper down toward to distal ends thereof. Each first branch area 40A and each second branch area 40B may have a constant width from the proximal ends to the distal ends or may have other shapes.

The end area 50 is connected to one end of the axis area 30. First gap areas 60A are formed between the first branch areas 40A. Second gap areas 60B are formed between the second branch areas 40B.

In the example shown in FIG. 13, a center CIA of each first branch area 40A in the second direction D2 and a center C1B of each second branch area 40B in the second direction D2 are on the same straight line. Further, a center C2A of each first gap area 60A in the second direction D2 and a center C2B of each second gap area 60B in the second direction D2 are on the same straight line. However, the center CIA and the center C1B may not be aligned with each other in the second direction D2. Similarly, the center C2A and the center C2B may not be aligned with each other in the second direction D2.

The branch area 40A has a first side 41A and a second side 42A. The second area 40B has a first side 41B and a second side 42B. When voltage is applied between the pixel electrode PE and the common electrode CE, the liquid crystal molecules LM in the vicinity of the first side 41A and the liquid crystal molecules LM in the vicinity of the second side 42B rotate in the first rotation direction R1. Further, the liquid crystal molecules LM in the vicinity of the first side 41B and the liquid crystal molecules LM in the vicinity of the second side 42A rotate in the second rotation direction R2. On the other hand, the liquid crystal molecules LM are maintained in the initial alignment state and hardly rotate in the vicinities of the centers C1A, C1B, C2A and C2B. Therefore, the sub-pixel area A has such a luminance distribution that the luminance is high in the vicinities of the sides 41A, 42A, 41B and 42B and the luminance is low in the vicinities of the centers CIA, C2A, C1B and C2B.

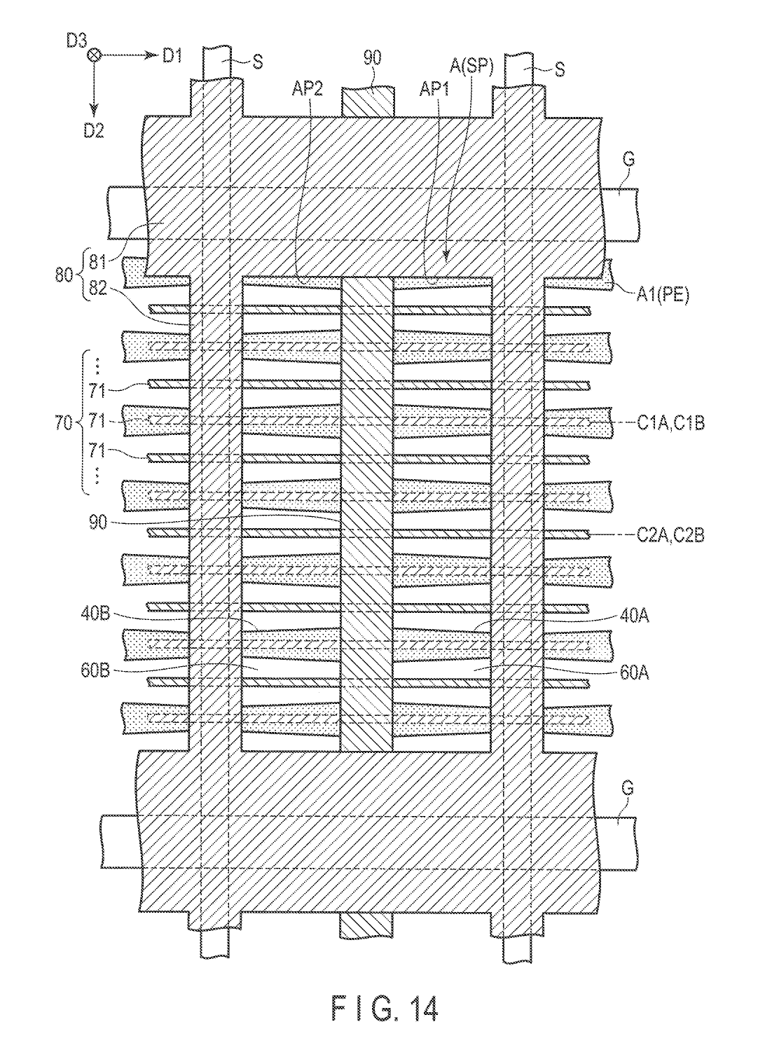

FIG. 14 is a plan view schematically showing an arrangement example of the light-shielding layer in the present embodiment. In the present embodiment, a third light-shielding layer 90 is provided in addition to the first light-shielding layer 70 and the second light-shielding layer 80. The third light-shielding layer 90 overlaps the axis area 30 and extends in the second direction D2. In the sub-pixel area A, a first aperture AP1 and a second aperture AP2 are formed by the second light-shielding layer 80 and the third light-shielding layer 90. The first aperture AP1 includes the first branch areas 40A and the first gap areas 60A, and the second aperture AP2 includes the second branch areas 40B and the second gap areas 60B.

The first portions 71 of the first light-shielding layer 70 overlap the centers CIA and C1B of the branch areas 40A and 40B and the centers C2A and C2B of the gap areas 60A and 60B. The arrangement manner, shape, etc., of the first portions 71 are the same as those of the first embodiment.

The width of the third light-shielding layer 90 in the first direction D1 is greater than the width of the first portion 71 in the second direction D2 and is less than the width of the scanning line light-shielding portion 81 in the second direction D2. The third light-shielding layer 90 can be arranged on the second substrate SUB2 together with the second light-shielding layer 80, for example. In this case, the second light-shielding layer 80 and the third light-shielding layer 90 may be arranged on the same layer. Further, the third light-shielding layer 90 can be arranged on the first substrate SUB1 together with the first light-shielding layer 70. In that case, the first light-shielding layer 70 and the third light-shielding layer 90 may be arranged on the same layer.

Even when the first area A1 (pixel electrode PE) has the shape of the present embodiment, the same effect as that produced from the first embodiment can be produced by shielding the respective portions from light as shown in FIG. 14.

### Third Embodiment

The third embodiment will be described. In the present embodiment, the display device 1 having the function of a touch sensor will be disclosed. Unless otherwise specified, the present embodiment has the same structure and effect as those of the above-described embodiments.

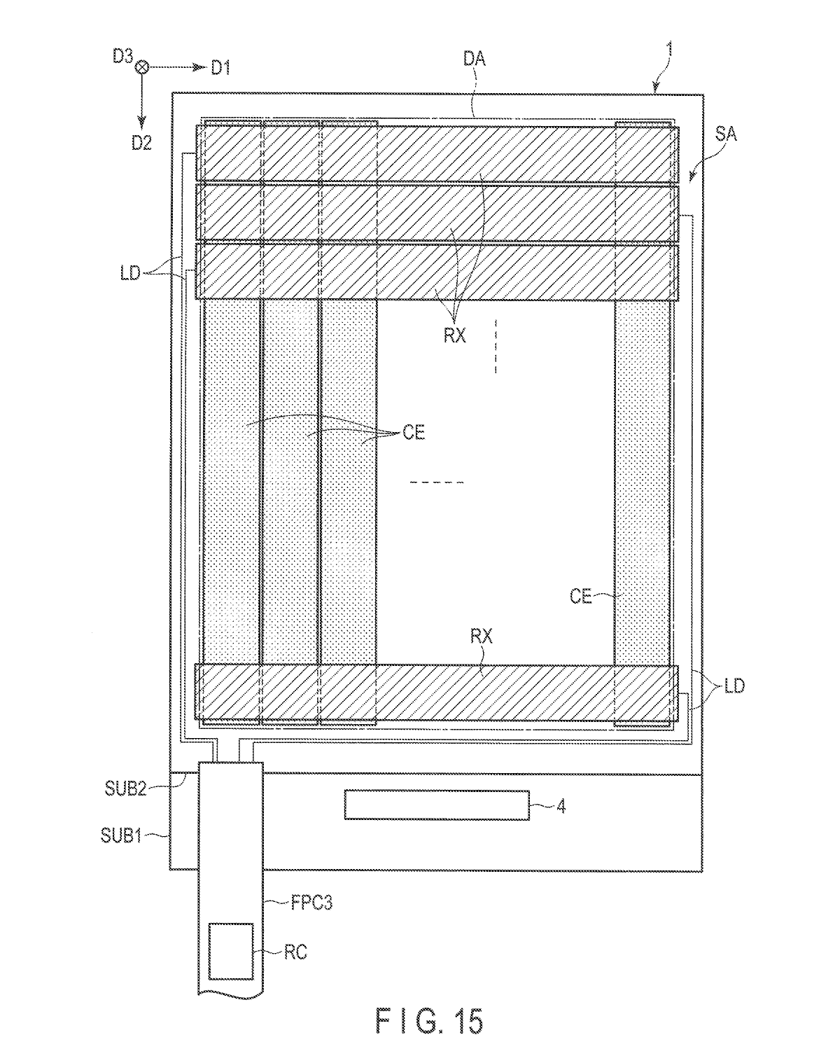

FIG. 15 is a schematic plan view of the display device 1 of the present embodiment and mainly shows a structure related to a touch sensor. The display device 1 includes a plurality of detection electrodes RX, a flexible printed circuit board FPC3 and a detection circuit RC in addition to the structural elements disclosed in the above-described embodiments. The display device 1 further includes a plurality of common electrodes CE.

The detection electrodes RX extend in the first direction D1 and are arranged in the second direction D2 in the display area DA. The common electrodes CE extend in the second direction D2 and are arranged in the first direction D1 in the display area DA. The detection electrodes RX are connected to the flexible printed circuit board FPC3 via lead lines LD arranged in a surrounding area SA around the display area DA. In the example shown in FIG. 15, the detection circuit RC is mounted on the flexible printed circuit board FPC3. However, the detection circuit RC may be provided in another manner and may be incorporated in the driver IC 4, for example.

In the present embodiment, each common electrode CE functions as an electrode for displaying an image and also functions as an electrode for detecting a conductor such as a user's finger which contacts or approaches the display area DA.

In the detection of a conductor, a drive signal having a predetermined waveform is supplied to each common electrode CE. Capacitance is formed between the common electrode CE and the detection electrode RX which are opposed to each other. A detection signal having a waveform corresponding to the drive signal is output from the detection electrode RX via the capacitance. When a conductor contacts or approaches the display area DA, the waveform of a detection signal changes. The detection circuit RC detects the presence or absence and the position of a conductor which contacts or approaches the display area DA based on the waveform of a detection signal. The above-described detection method is called a mutual-capacitive detection method, etc.

The mutual-capacitive detection method applicable to the display device 1 is not limited to a mutual-capacitive detection method and may be a self-capacitive detection method. In this method, for example, a drive signal is supplied to the common electrode CE, and a detection signal is read from the common electrode CE.

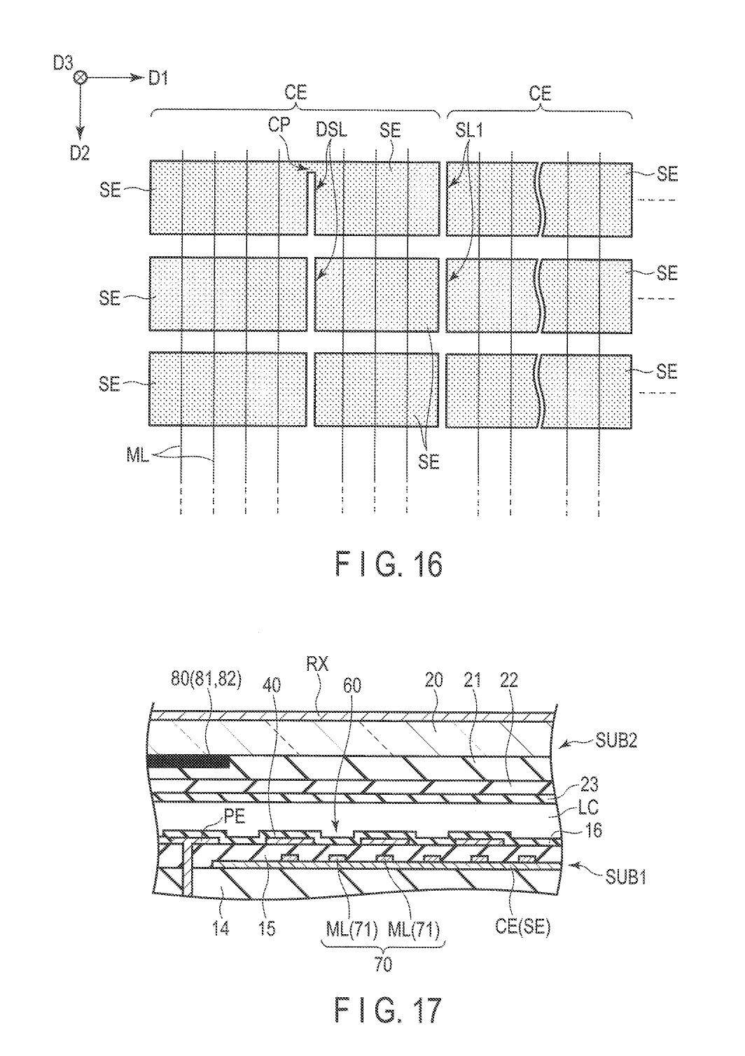

FIG. 16 is a plan view schematically showing the structure of the common electrode CE in the present embodiment. Each common electrode CE includes a plurality of structural electrodes SE which are arranged in the second direction D2. Each structural electrode SE extends over a plurality of sub-pixels SP which are arranged in the first direction D1, for example. In the second direction D2, each structural electrode SE may extend over a plurality of sub-pixels SP or may correspond to one sub-pixel SP. The structural electrodes SE which constitute one common electrode CE are electrically connected to each other by a plurality of metal lines ML. For example, the metal lines ML overlap the signal lines S and extend along the signal lines S. As the structural electrodes SE are connected to each other by the metal lines ML which have a lower resistance than transparent conductive materials such as ITO, the overall resistance of the common electrode CE can be reduced.

Each common electrode CE may not be formed of a plurality of structural electrodes SE but may be formed into a strip which extends continuously between both ends of the display area DA in the second direction D2.

A slit SL1 is formed between adjacent common electrodes CE. The slit SL1 corresponds to a gap between the structural electrode SE included in one common electrode CE and the structural electrode SE included in another common electrode CE. Further, a dummy slit DSL may be formed in the common electrode CE. The dummy slit DSL corresponds to a gap between the structural electrodes SE which are adjacent to each other in the first direction D1 in one common electrode CE. In the example shown in FIG. 16, two structural electrodes SE on the uppermost stage which are adjacent to each other via the dummy slit DSL are electrically connected to each other via a connecting portion CP. Accordingly, the structural electrodes SE which are adjacent to each other via the dummy slit DSL have the same potential. The arrangement manner of the connecting portion CP is not limited to the example shown in FIG. 16.

FIG. 17 is a schematic sectional view of the display device 1 according to the present embodiment. The detection electrode RX is arranged on the second base 20 of the second substrate SUB2. The metal line ML is arranged on the common electrode CE (structural electrode SE). The metal line ML may be arranged below the common electrode CE (structural electrode SE).

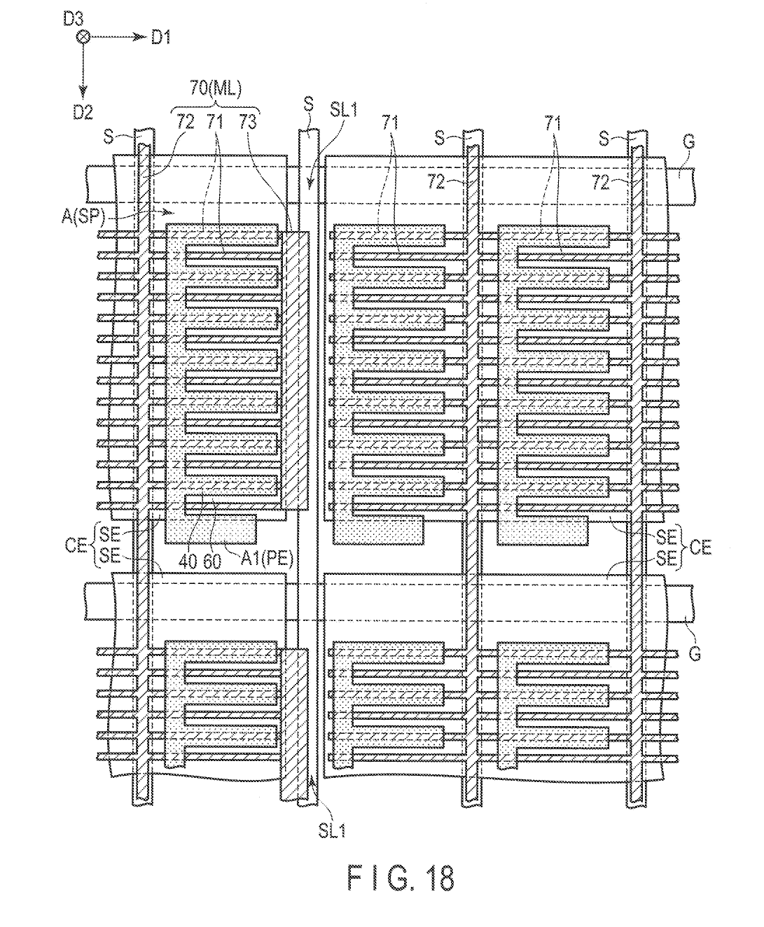

In the present embodiment, the metal line ML is used as the first light-shielding layer 70. An arrangement example of the first light-shielding layer 70 will be described with reference to a plan view shown in FIG. 18.

FIG. 18 shows two scanning lines G, four signal lines S, the pixel electrodes PE and the common electrodes CE (structural electrodes SE), in addition to the first light-shielding layer 70 formed of the metal lines ML. The first light-shielding layer 70 includes the first portion 71, a second portion 72 and a third portion 73. The first light-shielding layer 70 does not have to include the third portion 73.

The illustrated pixel electrode PE (first area A1) has the same shape as that of the example shown in FIG. 3. However, the pixel electrode PE does not necessarily have this shape and may have the shape shown in FIG. 13 or another shape. The first portions 71 overlap the branch areas 40 and the gap areas 60 as is the case with the example shown in FIG. 5. The second portions 72 overlap the signal lines S and extend along the signal lines S. Between the second portions 72 which are adjacent to each other without the intervention of the slit SL1 (or the dummy slit DSL), the first portions 71 are connected to both of the second portions 72. However, the first portions 71 may not be connected one of the second portions 72. Between the second portions 72 which are adjacent to each other via the slit SL1 (or the dummy slit DSL), the first portions 71 extend from the second portions 72, respectively. Further, a gap is created between the distal ends of the first portions 71 which extend from one second portion 72 and the distal ends of the first portions 71 which extend from the other second portion 72.

For example, the width of the second portion 72 in the first direction D1 is greater than the width of the first portion 71 in the second direction D2 and is less than the width of the signal line S in the first direction D1. However, the width of the first portion 71, the width of the second portion 72 and the width of the signal line S are not limited to this relationship.

The third portion 73 overlaps part of the slit SL1 between the structural electrodes SE which are adjacent to each other in the first direction D1. However, the third portion 73 does not contact both of the structural electrodes SE which are adjacent to each other in the first direction D1. The third portion 73 may contact one of the structural electrodes SE located left side in FIG. 18. The third portion 73 is connected to the first portions 71. Although the third portion 73 is arranged in the slit SL1 in the example shown in FIG. 18, the third portion 73 may be similarly arranged in the dummy slit DSL.

Although not shown in FIG. 18, the second portion 72 and the third portion 73 overlap the signal line light-shielding portions 82 of the second light-shielding layer 80.

In the above-described structure also, as is the case with the above-described embodiments, positions at which the contrast ratio between the on state and the off state is low in the sub-pixel area A are shielded from light, and the overall contrast ratio is improved, accordingly.

Further, in the present embodiment, the metal line ML is used as the first light-shielding layer 70, and therefore the first light-shielding layer 70 will not be provided separately.

The intensity and distribution of the electric field applied to the liquid crystal layer LC vary between the positions of the slit SL1 and the dummy slit DSL and the other positions. As a result, the liquid crystal molecules lose alignment and the display quality may be degraded at positions at which the slit SL1 and the dummy slit DSL are formed. If the third portions 73 as conductors are arranged in the slit SL1 and the dummy slit DSL as in the present embodiment, this impact can be reduced.

### Fourth Embodiment

The fourth embodiment will be described. In the present embodiment, another example of the display device 1 having the function of a touch sensor will be described. Unless otherwise specified, the present embodiment has the same structure and effect as those of the above-described embodiments.

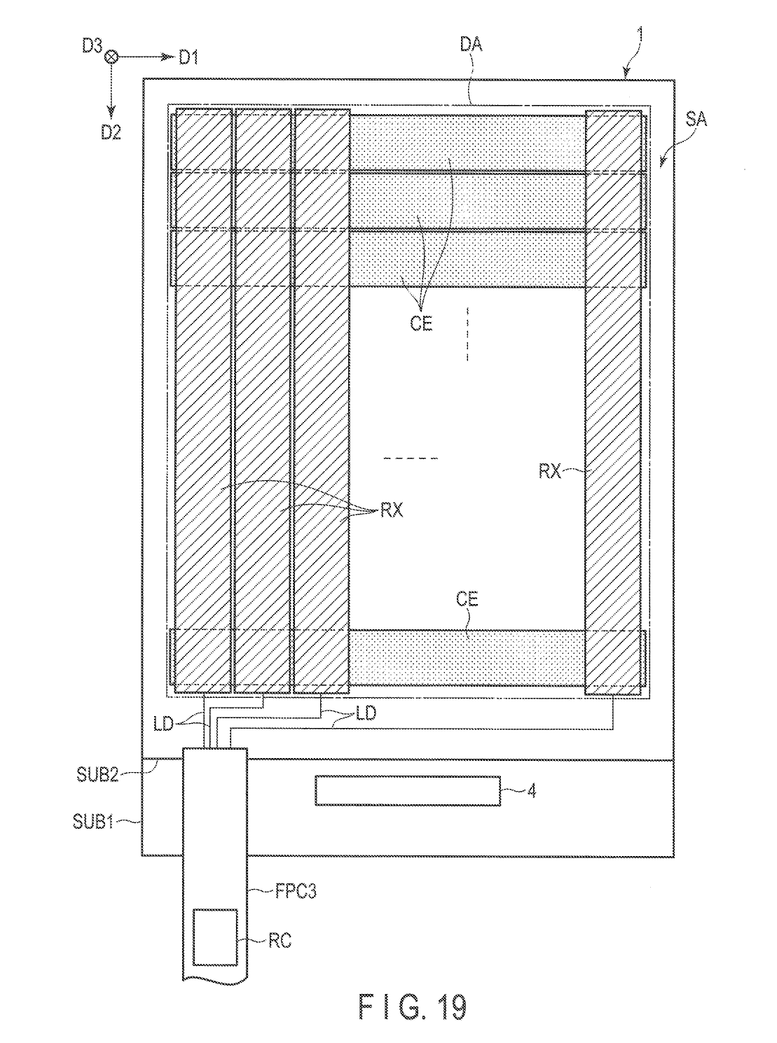

FIG. 19 is a schematic plan view of the display device 1 of the present embodiment and mainly shows a structure related to a touch sensor. In the present embodiment, the detection electrodes RX extend in the second direction D2 and are arranged in the first direction D1, and the common electrodes CE extend in the first direction D1 and are arranged in the second direction D2.

In the present embodiment also, the metal line ML is used as the first light-shielding layer 70 as is the case with the third embodiment.

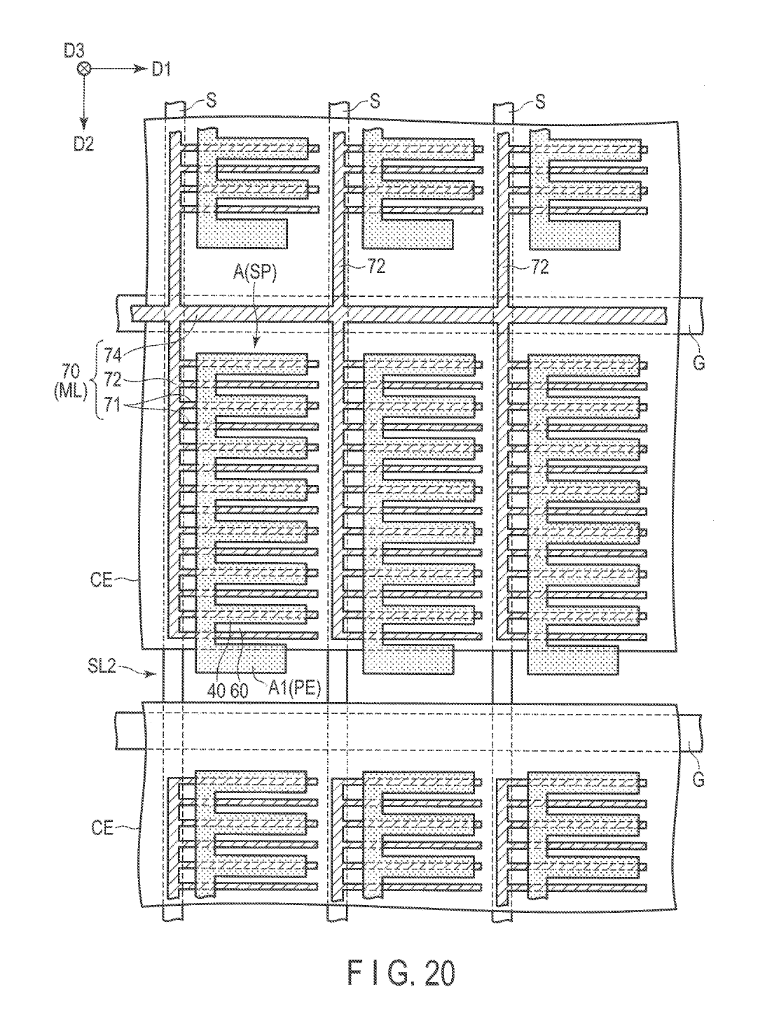

FIG. 20 is a plan view schematically showing an arrangement example of the first light-shielding layer 70 in the present embodiment. The drawing shows two scanning lines G, three signal lines S, the pixel electrodes PE and the common electrodes CE, in addition to the first light-shielding layer 70 formed of the metal lines ML. The first light-shielding layer 70 includes the first portion 71, the second portion 72 and a fourth portion 74. The shape of the pixel electrode PE (first area A1) is the same as that of the example shown in FIG. 18. However, the pixel electrode PE does not necessarily have this shape and may have the shape shown in FIG. 13 or another shape.

The first portions 71 are arranged in about the same manner as that of the example shown in FIG. 18, but in the example shown in FIG. 20, the first portions 71 are connected only to one of the two second portions 72 which are adjacent to each other in the first direction D1. That is, of the two second portions 72 which are adjacent to each other in the first direction D1, a gap is created between the distal ends of the first portions 71 connected to one second portion 72, and the other second portion 72. However, the first portions 72 may be connected to the adjacent second portions 72, respectively, as is the case with the example shown in FIG. 18.

Each common electrode CE has the shape of a strip which extends continuously between both ends of the display area DA in the first direction D1, for example. A slit SL2 is formed between the common electrodes CE which are adjacent to each other in the second direction D2. Each second portion 72 extends along the signal line S but is not provided at the position of the slit SL2.

The fourth portion 74 overlaps the scanning line G and extends along the scanning line G. The second portions 72 which are arranged in the first direction D1 are connected to the fourth portion 74.

Each common electrode CE may include the structural electrodes SE which are arranged in the first direction D1. In this case, a slit is formed between the structural electrodes SE which are adjacent to each other in the first direction D1. The third portion 73 similar to that of the example shown in FIG. 18 may be arranged in the slit.

Although not shown in FIG. 20, the second portion 72 overlaps the signal line light-shielding portion 82, and the fourth portion 74 overlaps the scanning line light-shielding portion 81.

The same effect as that produced from the third embodiment can be produced from the above-described structure.

### Fifth Embodiment

The fifth embodiment will be described. In the present embodiment, another example of the display device 1 having the function of a touch sensor will be described. Unless otherwise specified, the present embodiment has the same structure and effect as those of the above-described embodiments.

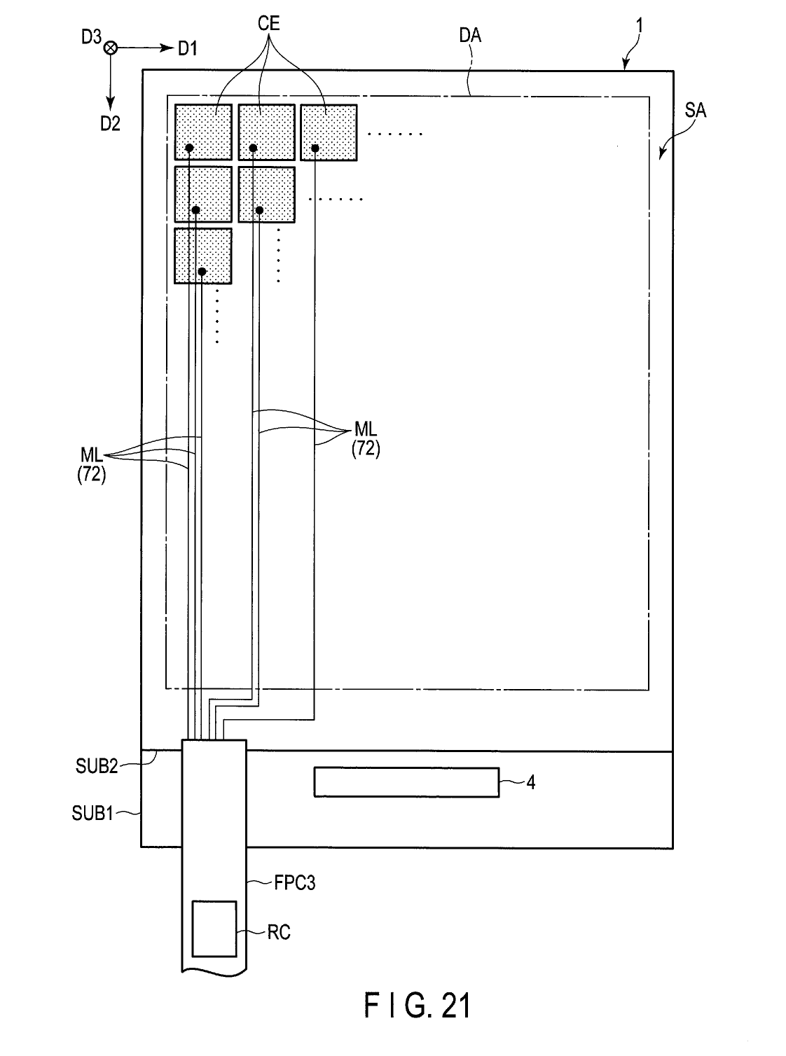

FIG. 21 is a schematic plan view of the display device 1 of the present embodiment and mainly shows a structure related to a touch sensor. In the present embodiment, the common electrodes CE are arranged in the first direction D1 and the second direction D2 in the display area DA. Further, for example, one metal line ML is provided for each common electrode CE. Each metal line ML electrically connects the corresponding common electrode CE and the flexible printed circuit board FPC3.

The display device 1 of the present embodiment detects a conductor which contacts or approaches the display area DA by the above-described self-capacitive detection method. That is, the detection circuit RC supplies a drive signal to each common electrode CE via the metal line ML and reads a detection signal from each common electrode CE via the metal line ML. A drive signal may be supplied from the driver IC 4 to each common electrode CE.

In the present embodiment also, the metal line ML is used as the first light-shielding layer 70 as is the case with the third and fourth embodiments. The metal line ML shown in FIG. 21 mainly corresponds to the second portion 72 of the first light-shielding layer 70 but also includes the first portion 71 of the first light-shielding layer 70.

In this structure, the metal line ML connected to a certain common electrode CE overlaps the common electrodes CE shown on the lower side of this common electrode CE in the drawing. If the metal lines ML are arranged on the common electrodes CE as shown in FIG. 17, the metal lines ML are electrically connected to all the overlapping common electrodes CE. Therefore, an insulating layer is interposed between the metal line ML and the common electrode CE in the present embodiment.

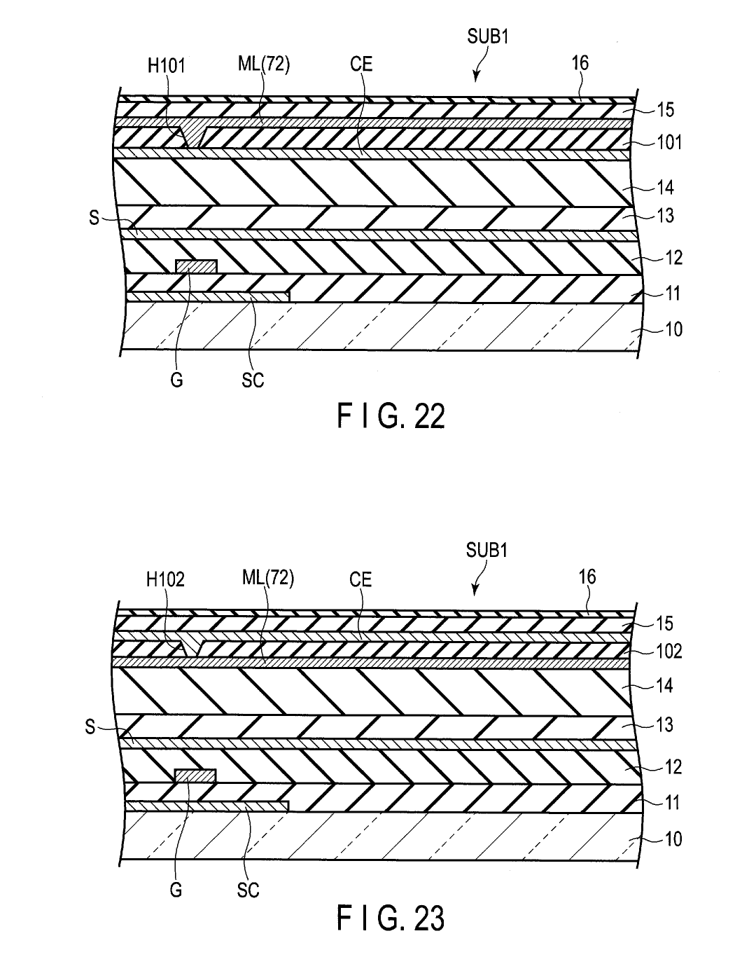

FIGS. 22 and 23 show the structure of the first substrate SUB1 applicable to the present embodiment. These drawings schematically show cross-sections of the first substrate SUB1 along the second portion 72 of the metal line ML (the first light-shielding layer 70).

In the example shown in FIG. 22, the common electrode CE is arranged on the fourth insulating layer 14 and is covered with an insulating layer 101. The metal line ML is arranged on the insulating layer 101 and is covered with the fifth insulating layer 15. The metal line ML contacts the common electrode CE via a contact hole H101 provided in the insulating layer 101.

In the example shown in FIG. 23, the metal line ML is arranged on the fourth insulating layer 14 and is covered with an insulating layer 102. The common electrode CE is arranged on the insulating layer 102 and is covered with the fifth insulating layer 15. The common electrode CE contacts the metal line ML via a contact hole H102 provided in the insulating layer 102.

In FIGS. 22 and 23, the contact holes H101 and H102 are provided in the intersection area of the scanning line G and the signal line S. However, the contact holes H101 and H102 are not necessarily provided at the position in this example.

The common electrode CE and the metal line ML may be connected to each other via another conductive layer. For example, two insulating layers may be arranged between the common electrode CE and the metal line ML and a conductive layer may be interposed between these insulating layers, and the common electrode CE may contact the conductive layer via a contact hole provided in one insulating layer and the metal line ML may contact the conductive layer via a contact hole provided in the other insulating layer.

According to the above-described structure, the metal line ML can be connected only to the corresponding common electrode CE. As a result, a touch sensor conforming to a self-capacitive detection method using the common electrode CE can be realized. In addition, the same effect as those produced from the above-described embodiments can be produced from the present embodiment.

### Sixth Embodiment

The sixth embodiment will be described. The following description will be mainly focused on a difference from the above-described embodiments, and the description of the same structure as those of the above-described embodiment will be omitted unless necessary.

The present embodiment differs from the above-described embodiments in that the common electrode CE is arranged between the pixel electrode PE and the liquid crystal layer LC. A structure which will be described below can be appropriately applied to the above-described embodiments.

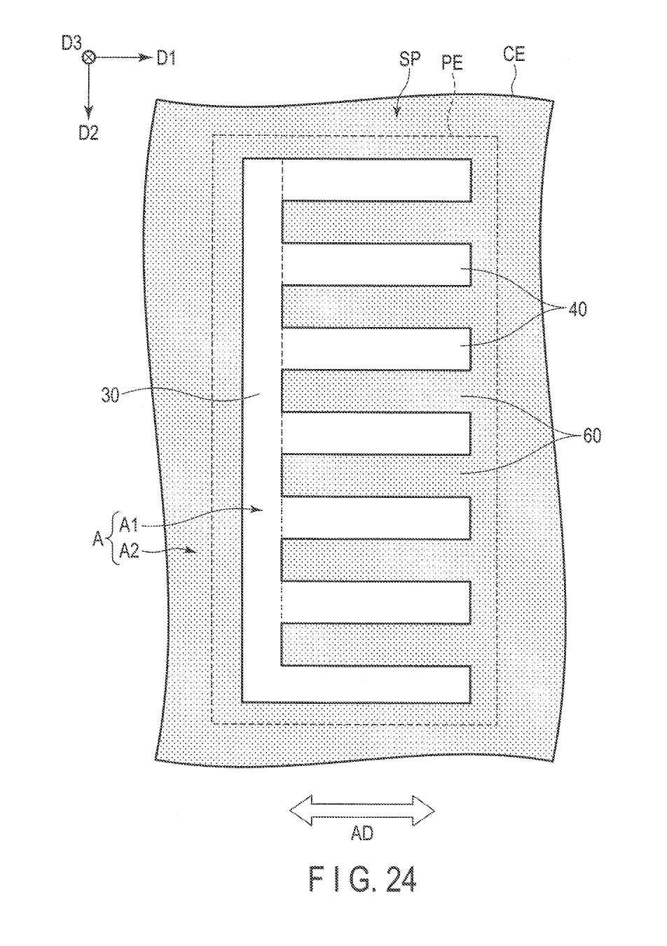

FIG. 24 is a plan view schematically showing the common electrode CE and the pixel electrode PE according to the present embodiment. The drawing mainly shows the sub-pixel area A corresponding to one sub-pixel SP. In the example illustrated, the sub-pixel area A has the first area A1 and the second area A2 as is the case with FIG. 3. Further, the first area A1 has the axis area 30 and the branch areas 40, and the second area A2 has the gap areas 60. In the present embodiment, the first area A1 is an area in which the common electrode CE is not provided, and the second area A2 is an area in which the common electrode CE is provided. That is, the first area A1 is a slit (opening) having the axis area 30 and the branch areas 40. In other words, the common electrode CE has the slit. The first area A1 does not necessarily have the illustrated shape and may have the shape shown in FIG. 13 or another shape. The pixel electrode PE has an outer shape shown as a frame by a dashed line, for example, and overlaps the first area A1 in a planar view.

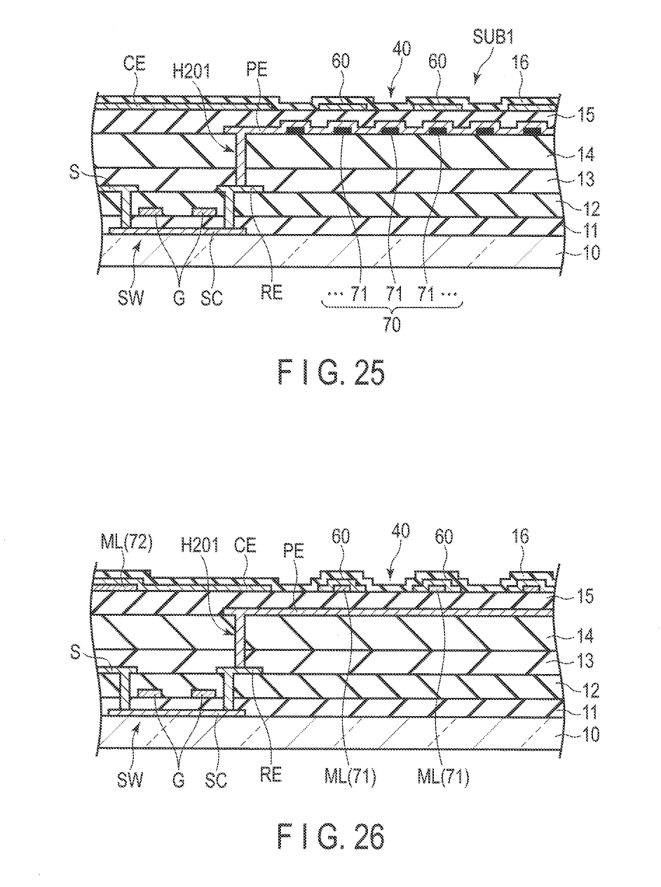

FIG. 25 shows part of a cross-section of the display device 1 according to the present embodiment. Only the first substrate SUB1 is illustrated in the drawing, and the second substrate SUB2 and the liquid crystal layer LC are not illustrated in the drawing. The pixel electrode PE is arranged on the fourth insulating layer 14 and is covered with the fifth insulating layer 15. The common electrode CE is arranged on the fifth insulating layer 15 and is covered with the first alignment film 16. The pixel electrode PE contacts the relay electrode RE via a contact hole H201 which penetrates the third insulating layer 13 and the fourth insulating layer 14.

The first light-shielding layer 70 is formed of an insulating resin material as is the case with the first embodiment, for example. The first portions 71 of the first light-shielding layer 70 are arranged on the fourth insulating layer 14 and are covered with the pixel electrode PE. The first portions 71 may be arranged on another layer which is closer to the liquid crystal layer LC than the scanning line G, the signal line S, the semiconductor layer SC and the relay electrode RE, for example, on the pixel electrode PE or the third insulating layer 13, etc. The first portions 71 overlap the branch areas 40 and the gap areas 60 in a plan view as is the case with the example shown in FIG. 5, for example. The first portions 71 of the first light-shielding layer 70 may contain a conductive metal material.

FIG. 26 shows another cross-section applicable to the first substrate SUB1. This drawing corresponds to a structure of a case where the metal line ML is used as the first light-shielding layer 70 as is the case with the third and fourth embodiments. That is, the metal lines ML as the first portion 71 and the second portion 72 are arranged on the fifth insulating layer 15 and are covered with the common electrode CE.

The metal lines ML can also be used as the third portion 73 and the fourth portion 74. The metal line ML may be arranged on the common electrode CE. Further, an insulating layer may be interposed between the metal line ML and the common electrode CE as is the case with the example shown in FIG. 22 or the example shown in FIG. 23. Since the metal line ML and the common electrode CE have the same potential, if the metal line ML is elongated in the axis area 30 or the branch area 40, the metal line ML may affect the distribution of an electric field which acts on the liquid crystal layer LC. In FIG. 26, the first portion 71 is arranged only in the gap area 60 in which the common electrode CE is provided, and the first portion 71 is not arranged in the branch area 40 in which the common electrode CE is not provided. In this case also, the area having a low contrast ratio at the center of the gap area 60 can be shielded from light, and the overall contrast ratio of the sub-pixel area A can be improved.

The first portions 71 which overlap the gap areas 60, the second portion 72, the third portion 72 and the fourth portion 74 can be arranged in the manner shown in FIG. 18 or the manner shown in FIG. 20, for example.

In the structure of the present embodiment also, the display device 1 conforming to the high-speed response mode can be realized. Further, it is possible to improve the contrast of the display device 1 by arranging the first light-shielding layer 70.

In the first to sixth embodiments, a structure applicable to a case where the liquid crystal molecules of the liquid crystal layer LC have positive dielectric anisotropy has been described. However, the liquid crystal layer LC can also be formed of liquid crystal molecules having negative dielectric anisotropy. In this case, the alignment treatment direction AD (the initial alignment direction of the liquid crystal molecules) only needs to be set to the direction (second direction D2) orthogonal to the extension direction (first direction D1) of the branch area 40.

Based on the display device described as the embodiment of the present invention, a person of ordinary skill in the art can implement various display devices by making arbitrary design changes, and all the display devices will come within the scope of the present invention as long as they covers the spirit of the present invention.

A person of ordinary skill in the art could conceive various modifications of the present invention within the scope of the technical concept of the present invention, and such modifications will be encompassed by the scope and spirit of the present invention. For example, a person of ordinary skill in the art may make an addition, a deletion or a design change of a structural element, or make an addition, an omission or a condition change of a manufacturing process to the above-described embodiments, and such a change will also come within the scope of the present invention as long as they fall within the spirit of the present invention.

Further, when it comes to advantages other than those described in the embodiments, advantages obvious from the description of the present invention and advantages appropriately conceivable by a person of ordinary skill in the art will be regarded as advantages achievable from the present invention as a matter of course.

What is claimed is:

1. A liquid crystal display device comprising:
a first substrate;
a second substrate opposed to the first substrate; and
a liquid crystal layer between the first substrate and the second substrate, wherein
the first substrate includes a plurality of scanning lines, a plurality of signal lines which intersect the scanning lines, a first electrode, a second electrode opposed to the first electrode, and a light-shielding layer,
one of the first electrode and the second electrode is a pixel electrode, and the other one of the first electrode and the second electrode is a common electrode,
the first electrode includes a plurality of branch areas which extend in a first direction, and an axis area which extends in a second direction intersecting, the first direction and connects the branch areas,
a gap area is provided between the branch areas which are adjacent to each other, and the gap area extends in the first direction,
the light-shielding layer includes a plurality of first portions, each of the first portions overlaps the branch area or the gap area, and the first portions extend in the first direction and are arranged in the second direction, and
the first portions are arranged at a position which is closer to the liquid crystal layer than the scanning lines and the signal lines in the first substrate.

2. The liquid crystal display device of claim 1, wherein the first electrode and the second electrode are formed of a transparent conductive material.

3. The liquid crystal display device of claim 1, wherein
the first portions overlap the branch areas in a plan view, and
each of the first portions overlaps a center of the branch area in the second direction and does not overlap a pair of sides of the branch area which are arranged in the second direction.

4. The liquid crystal display device of claim 1, wherein each of the first portions overlaps the branch areas which are arranged in the first direction in a plan view.

5. The liquid crystal display device of claim 1, wherein
the first portions overlap the gap areas in a plan view,
each of the first portions overlaps a center of the gap area in the second direction and does not overlap sides of the two branch areas which are adjacent to the gap area.

6. The liquid crystal display device of claim 1, wherein each of the first portions overlaps the gap areas which are arranged in the first direction.

7. The liquid crystal display device of claim 1, wherein the light-shielding layer further includes a second portion which extends along the signal line.

8. The liquid crystal display device of claim 7, wherein the first portions and the second portion are connected to each other.

9. The liquid crystal display device of claim 7, wherein a width of the second portion in the first direction is greater than a width of the first portions in the second direction.

10. The liquid crystal display device of claim 7, wherein a width of the second portion in the first direction is less than a width of the signal line in the first direction.

11. The liquid crystal display device of claim 1, comprising the common electrodes which extend in an extension direction of the signal lines and are arranged in an extension direction of the scanning lines, wherein
a slit is provided between the common electrodes which are adjacent to each other,
the light-shielding layer further includes a third portion which overlaps part of the slit, and
the first portions and the third portion are connected to each other.

12. The liquid crystal display device of claim 11, wherein the third portion contacts one of the two common electrodes which are adjacent to each other via the slit, and does not contact the other one of the two common electrodes.

13. The liquid crystal display device of claim 7, comprising the common electrodes which extend in an extension direction of the scanning lines and are arranged in an extension direction of the signal lines, wherein
the light-shielding layer further includes a fourth portion which extends along the scanning line.

14. The liquid crystal display device of claim 13, the second portion and the fourth portion are connected to each other.

15. The liquid crystal display device of claim 1, wherein the light-shielding layer is a metal layer and is electrically connected to the common electrode.

16. The liquid crystal display device of claim 15, wherein
the first substrate further includes an insulating layer which is arranged between the light-shielding layer and the common electrode, and
the light-shielding layer and the common electrode are opposed to each other via the insulating layer.

17. The liquid crystal display device of claim 1, wherein the common electrode is arranged between the light-shielding layer and the pixel electrode.

18. The liquid crystal display device of claim 1, wherein the light-shielding layer is arranged between the pixel electrode and the common electrode.

19. The liquid crystal display device of claim 1, further comprising a detection circuit configured to detect contact or approach of a conductor based on a signal which is output from the common electrode.

20. The liquid crystal display device of claim 1, wherein
the first substrate further includes a color filter, and
the light-shielding layer is formed of a resin material and is arranged at a position which is closer to the liquid crystal layer than the color filter.
